(19) United States
(12) Patent Application Publication
(10) Pub. No.: US 2010/0140733 A1
(43) Pub. Date: Jun. 10, 2010

(54) Back-side illuminated image sensor

(75) Inventors: Yong Jei Lee, Seongnam-si (KR); Jung Chak Ahn, Yongin-si (KR); Jong Eun Park, Seongnam-si (KR); Dong-Yoon Jang, Hwasung-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,912

(22) Filed: Dec. 4, 2009

(30) Foreign Application Priority Data
Dec. 5, 2008 (KR) 10-2008-0123256

(51) Int. Cl. H01L 31/02

(52) U.S. Cl. 257/447; 257/E31.11

(57) ABSTRACT

In an example embodiment, the backside-illuminated image sensor includes a substrate including a plurality of photoelectric conversion devices being separated by a semiconductor. The backside-illuminated sensor further includes a transparent electrode layer or a metal layer formed on a surface of a substrate. As a positive bias voltage or a negative bias voltage is applied to the transparent electrode layer or the metal layer, generation of dark current in the surface of the silicon substrate may be reduced or suppressed.

### CROSS-REFERENCE TO RELATED APPLICATION

This application claims priority under 35 U.S.C. §119 to Korean Patent Application No. 10-2008-0123256, filed on 5 Dec., 2008, in the Korean Intellectual Property Office, the subject matter of which is incorporated herein in its entirety by reference.

### BACKGROUND

Example Embodiments relates to an image sensor, and more particularly, to a back-side illuminated image sensor which may suppress generation of dark current on an upper surface of a silicon substrate.

In general, an image sensor may include charge coupled device (CCD) image sensors or complementary metal-oxide semiconductor (CMOS) image sensors. The CMOS image sensor may include a plurality of pixels arranged in a 2D matrix format. Each pixel may output an image signal from light energy. Also, each pixel may accumulate light charges corresponding to the quantity of incident light on a photodiode and output a pixel signal based on the accumulated light charges.

Dark current may be generated due to a defect, dangling bond, or impurities on a surface of a substrate included in the image sensor. Since the dark current may work as considerable noise in the image sensor, a method to reduce or alternatively suppress the generation of dark current is desired or alternatively needed. In particular, since the surface area of the substrate of a back-side illuminated image sensor may be larger than that of other general image sensors, the amount of dark current that may be generated in the upper surface of a substrate may be increased. Accordingly, studies on the structure or method of an image sensor that may efficiently suppress the generation of dark current are widely being performed.

### SUMMARY

Example Embodiments provide a back-side illuminated image sensor which may provide a clear image by reducing or alternatively suppressing the generation of dark current on the surface of a substrate.

According to an aspect of an embodiment there is provided a back-side illuminated image sensor including a substrate. The substrate may include a plurality of photoelectric conversion devices, the photoelectric conversion devices may be separated by a semiconductor material. Additionally, a transparent electrode layer may be formed on the substrate and a voltage may be applied to the transparent electrode layer. The voltage applied may be a positive bias voltage or a negative bias voltage is applied.

The back-side illuminated image sensor may further include an insulation layer that may be formed under the transparent electrode layer. The transparent electrode layer may include at least one of an oxide material and a polymer material. The transparent electrode layer may be formed in a single pattern on a area of an active pixel sensor (APS) region. The transparent electrode layer may include a plurality of transparent electrodes corresponding to each pixel.

According to another aspect of an embodiment, there may be provided a back-side illuminated image sensor including a substrate including a plurality of photoelectric conversion devices. The photoelectric conversion devices may be separated by a semiconductor material, an insulation layer formed on the substrate, and a plurality of metal layers. The plurality of metal layers may be formed in an upper or lower portions of the insulation layer to be separated from each other.

When the plurality of metal layers may be formed in an upper portion of the insulation layer to be insulated from the substrate a negative bias voltage may be applied to each of the plurality of metal layers. When the plurality of metal layers may be formed in the lower portion of the insulation layer to be electrically connected to the substrate a positive bias voltage may be applied to each of the plurality of metal layers.

The back-side illuminated image sensor may be driven by a first power voltage and a second power voltage. The second power voltage may be higher than the first power voltage, wherein the negative bias voltage may be lower than the first power voltage and the positive bias voltage may be higher than the second power voltage.

### BRIEF DESCRIPTION OF THE DRAWINGS

Exemplary embodiments will be more clearly understood from the following detailed description taken in conjunction with the accompanying drawings in which:

FIG. 1 is a cross sectional view of a pixel array of a back-side illuminated image sensor according to an exemplary embodiment;

FIG. 2A is a graph for explaining a potential change when a negative (−) bias voltage is applied to the upper portion of a substrate included in a pixel array of a back-side illuminate image sensor according to an exemplary embodiment;

FIG. 2B is a graph for explaining a potential change when a positive (+) bias voltage may be applied to the upper portion of a substrate included in a pixel array of a back-side illuminate image sensor according to an exemplary embodiment

FIG. 3 is a cross sectional view of a pixel array of a back-side illuminated image sensor according to another exemplary embodiment;

FIG. 4 is a cross sectional view of a pixel array of a back-side illuminated image sensor according to another exemplary embodiment;

FIG. 5 is a cross sectional view of a pixel array of a back-side illuminated image sensor according to another exemplary embodiment;

FIGS. 6A and 6B are plan views of a pixel array of a back-side illuminated image sensor according to an exemplary embodiment;

FIG. 7 is a circuit diagram of a unit pixel included in a back-side illuminated image sensor according to an exemplary embodiment;

FIG. 8 is a block diagram of an image sensor according to an exemplary embodiment ; and

FIG. 9 is a block diagram of a semiconductor system including an image sensor according to an exemplary embodiment.

### DETAILED DESCRIPTION OF THE EMBODIMENTS

Example embodiments will now be described more fully with reference to the accompanying drawings, in which some example embodiments are shown. In the drawings, the thicknesses of layers and regions are exaggerated for clarity. Like reference numerals in the drawings denote like elements. In the drawings, the thicknesses of layers and regions are exaggerated for clarity.

Detailed illustrative embodiments are disclosed herein. However, specific structural and functional details disclosed herein are merely representative for purposes of describing example embodiments. Example embodiments, however, may be embodied in many alternate forms and should not be construed as limited to only the example embodiments set forth herein.

It should be understood, however, that there is no intent to limit the example embodiments to the particular example embodiments disclosed, but on the contrary example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

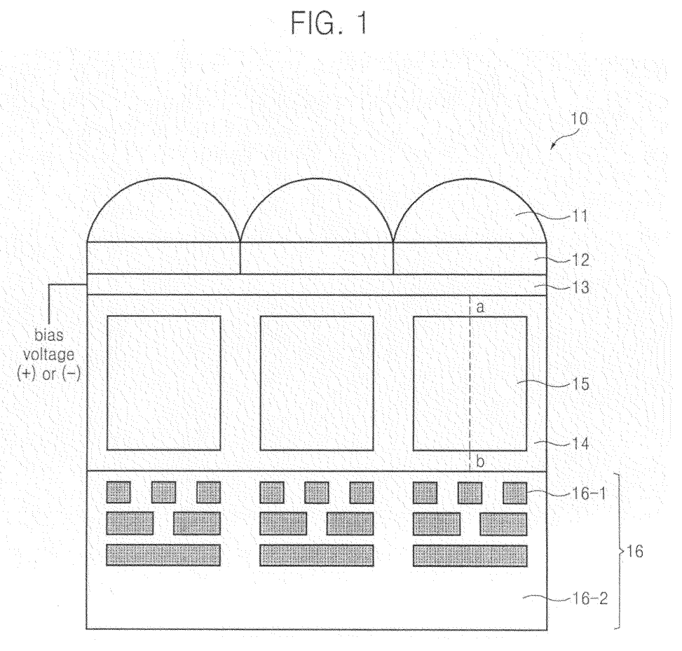

FIG. 1 is a cross sectional view of a pixel array 10 of a back-side illuminated image sensor according to an exemplary embodiment. In the following description, unless mentioned otherwise, the “image sensor” may be used instead of “back-side illuminated image sensor”, or vice versa.

Referring to FIG. 1, the pixel array 10 may include a microlens 11, a plurality of color filters 12, a transparent electrode layer 13, a substrate 14 including a plurality of photoelectric conversion devices 15, and a wiring pattern region 16. According to an exemplary embodiment, the photoelectric conversion devices 15 may be any one of photodiode (PD), a phototransistor, a photogate, and a pinned photodiode (PPD), or a combination thereof.

When light is externally incident on the microlens 11, the color filter 12 may perform filtering operation corresponding to any one of red, green, and blue colors with respect to the light received through the microlens 11. The substrate 14 may include the photoelectric conversion devices 15, each being separated from each other and generating electrons based on the incident light. For example, the substrate 14 may include p-type wells (not shown) and each of the photoelectric conversion devices 15 may be doped into n-type (not shown). Thus, the photoelectric conversion devices 15 may be insulated or isolated from each other by the p-type wells.

The wiring pattern region 16 may include a plurality of metal lines 16-1 and an inter-metal dielectric (IMD) 16-2. Additionally, electric wiring may be desired or alternatively needed for a sensing operation of the pixel array 10 may be formed by the metal lines 16-1. According to an exemplary embodiment, the metal lines 16-1 may reflect incident light having passed through the photoelectric conversion device 15 toward the photoelectric conversion device 15. Also, the pixel array 10 of an image sensor according to the present exemplary embodiment may include the transparent electrode layer 13 formed on the substrate 14. The transparent electrode layer 13 may be a transparent conductive material and may include an oxide such as indium tin oxide (ITO) or Zinc Oxide (ZnO), or a polymer material.

The transparent electrode layer 13 may be inserted between the substrate 14 and the color filter layer 12. As a negative bias voltage or a positive bias voltage is applied to the transparent electrode layer 13, the generation of dark current in the upper surface of the substrate 14 may be reduced or alternatively suppressed. According to an exemplary embodiment, the transparent electrode layer 13 may be formed in a single pattern on portions or alternatively the whole surface of an active pixel sensor (APS) region. In an example embodiment, while covering portions or alternatively the whole surface of the APS region, the transparent electrode layer 13 may be connected to a desired or alternatively predetermined pad (PAD).

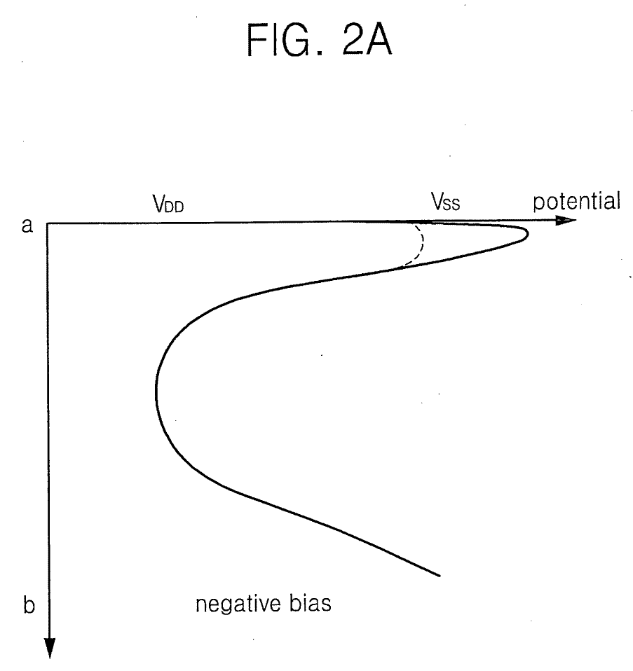

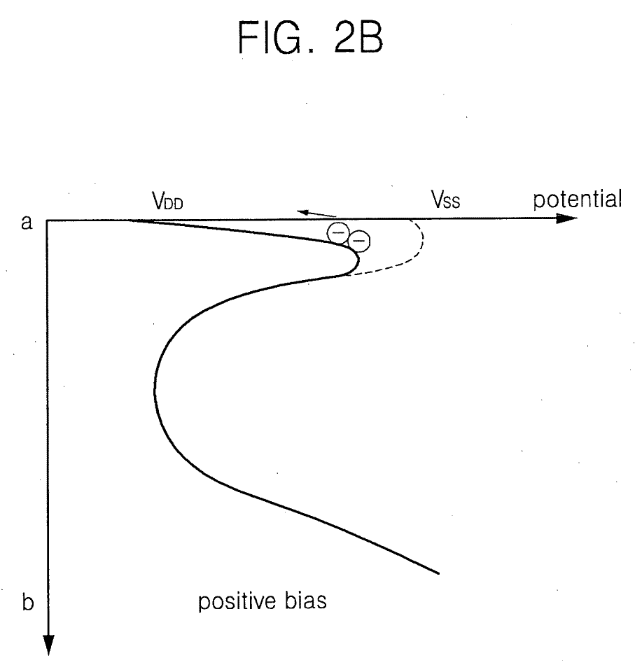

According to an exemplary embodiment, the transparent electrode layer 13 may be formed in multiple patterns corresponding to the respective pixels. The transparent electrode layer 13 may be patterned in units of pixels, a bias voltage may be applied to each pixel. The bias voltage may be applied directly from the pad or may be externally generated and applied. A method of efficiently removing or reducing dark current that may be generated in the upper surface of the substrate 14 when a positive bias voltage or a negative bias voltage is applied to the transparent electrode layer 13 will be described below with reference to FIGS. 2A and 2B.

FIG. 2A is a graph displaying a potential change when a negative (−) bias voltage is applied to the upper portion of a substrate included in a pixel array of a back-side illuminate image sensor according to an exemplary embodiment. Referring to FIGS. 1 and 2A, when a negative bias voltage is applied to the transparent electrode layer 13, potential changes along a sectional surface of the substrate 14 along a dotted line from “a” to “b” in FIG. 1. In FIG. 2A, a dotted line shows a potential graph when the pixel array 10 does not include the transparent electrode layer 13 and a solid line shows a potential graph when the pixel array 10 includes the transparent electrode layer 13. When a negative bias voltage is applied to the transparent electrode layer 13 formed in the upper surface of the substrate 14, potential increases in the upper surface of the substrate 14 so that holes may be accumulated n the upper surface of the substrate 14.

Thus, according to the semiconductor rule that the multiplication of a concentration, for example, “n”, of electrons and a concentration, for example, “p”, of holes should be constant, that is, n×p=ni², where “ni” is the intrinsic carrier concentration, when the density of holes increases n the upper surface of the substrate 14, the generation of electrons n the upper surface of the substrate 14 may be greatly reduced or suppressed.

The amount of holes that may be generated in the upper surface of the substrate 14 may be based on the negative bias voltage applied to the transparent electrode layer 13. Also, the negative bias voltage applied to the transparent electrode layer 13 may be lower than a drive voltage, for example, VSS of the image sensor according to the present exemplary embodiment. For example, when the VSS is 0V, the negative bias voltage may be not greater than −0.8V.

As describe above, the generation of electrons in the upper portion of the substrate 14 may be reduced or suppressed by applying a negative bias voltage to a dark current generation suppress device, for example, the transparent electrode layer 13, formed in the upper portion of the substrate 14. As a result, the generation of electrons in the upper portion of the substrate 14 may be reduced or suppressed. In the present exemplary embodiment, the thickness of the p-type semiconductor material located between the photoelectric conversion device 15 and the transparent electrode layer 13 may be implemented to be thin so that blue sensitivity deterioration is not or alternatively minimally generated.

FIG. 2B is a graph displaying a potential change when a positive (+) bias voltage is applied to the upper portion of a substrate included in a pixel array of a back-side illuminate image sensor according to an exemplary. Referring to FIGS. 1 and 2B, when a positive bias voltage is applied to the transparent electrode layer 13, potential changes along a sectional surface of the substrate 14 along a dotted line from “a” to “b” in FIG. 1. In FIG. 2B, a dotted line shows a potential graph when the pixel array 10 does not include the transparent electrode layer 13 and a solid line shows a potential graph when the pixel array 10 includes the transparent electrode layer 13. When a positive bias voltage is applied to the transparent electrode layer 13 formed in the upper surface of the substrate 14, potential decreases in the upper surface of the substrate 14 so that electrons generated in the upper surface of the substrate 14 do not flow toward the photoelectric conversion device 15 but are moved or alternatively drained to an external area of the upper surface of the substrate 14 having a lower potential. Accordingly, the generation of dark current in the substrate 14 may be reduced or suppressed. Also, the positive bias voltage applied to the transparent electrode layer 13 may be higher than a drive voltage, for example, VDD of the image sensor according to the present exemplary embodiment.

Thus, by applying a positive bias voltage to the transparent electrode layer 13 to have a potential lower than the photoelectric conversion device 15 that is doped into the n-type, the electrons generated in the surface of the substrate 14 may be reduced or alternatively prevented from flowing to the photoelectric conversion device 15. As describe above, the electrons generated in the upper portion of the substrate 14 may be moved or alternatively drained by applying a positive bias voltage to a dark current generation suppress device, for example, the transparent electrode layer 13, formed in the upper portion of the substrate 14. As a result, the generation of electrons in the upper portion of the substrate 14 may be suppressed.

In the present exemplary embodiment, since the positive bias voltage applied to the transparent electrode layer 13 may be generated by increasing the power voltage in the image sensor, it is easy to embody a pixel array and an image sensor having the pixel array.

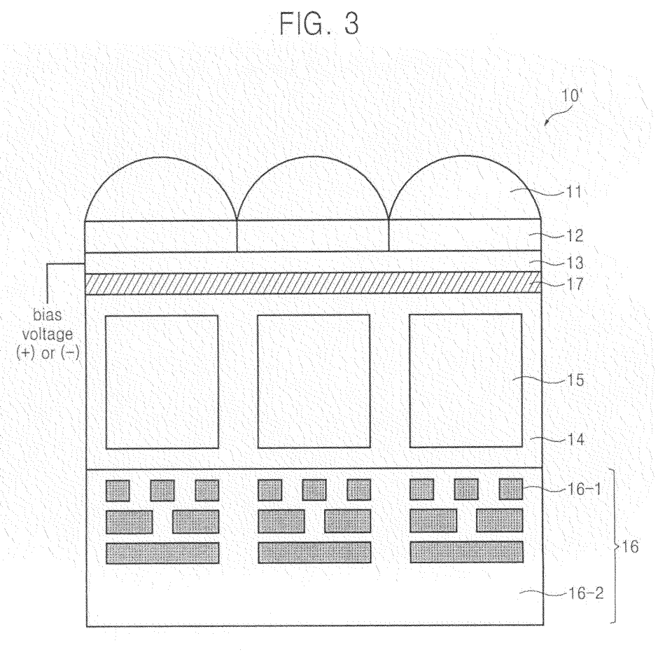

FIG. 3 is a cross sectional view of a pixel array of a back-side illuminated image sensor according to another exemplary. Referring to FIGS. 1 to 3, the pixel array 10′ of FIG. 3 may further include an insulation layer 17 between the substrate 14 and the transparent electrode layer 13. When a positive or negative bias voltage is applied to the transparent electrode layer 13 and the substrate 14 directly contacts the transparent electrode layer 13, a depth of potential changing by the bias voltage in the upper portion of the substrate 14 may exceed a required or alternatively predetermined depth.

It may be difficult to effectively remove dark current generated in the upper surface of the substrate 14. Accordingly, by additionally forming the insulation layer 17 on the substrate 14, a sharp potential curve may be formed in the upper surface area of the substrate 14. As described above, since the insulation layer 17 may be further provided between the substrate 14 and the transparent electrode layer 13 in the pixel array 10 according to the present exemplary embodiment and other members are substantially the same as those illustrated in FIG. 1, detailed descriptions thereon will be omitted herein.

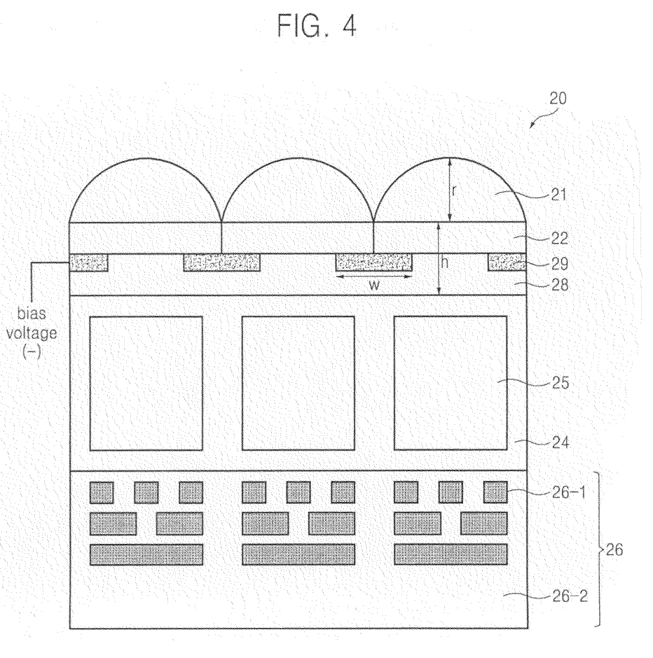

FIG. 4 is a cross sectional view of a pixel array 20 of a back-side illuminated image sensor according to another exemplary embodiment. Referring to FIG. 4, the pixel array 20 according to the present exemplary embodiment may include a substrate 24, an insulation layer 28, and a plurality of metal layers 29.

In FIG. 4, since a microlens 21, a color filter, 22, a photoelectric conversion device 25, a wiring pattern region 26, a metal line 26-1, and an IMD 26-2 are substantially the same as those illustrated in FIGS. 1 and 3, detailed descriptions thereof will be omitted herein. As illustrated in FIG. 4, the insulation layer 28 may be formed on the substrate 24 and the metal layers 29 may be formed in the upper portion of the insulation layer 28 to be separated from each other. Also, the color filter 22 may be formed on the upper surface of each of the metal layers 29.

In detail, as illustrated in FIG. 4, each of the metal layers 29 may be formed in a region between the photoelectric conversion devices 25. According to an exemplary embodiment, the insulation layer 28 may contain SiO₂. To form the pixel array 20, the insulation layer 28 may be formed on the substrate 24, a plurality of trench holes are formed in the insulation layer 28 by using a mask trench pattern, and the metal layers 29 may be formed in or on the trench holes.

Also, by applying a negative bias voltage to each of the metal layers 29, an electric potential of the upper surface of the substrate 24 may be increased. As a result, the generation of electrons in the upper surface of the substrate 24 may be reduced or suppressed. That is, the substantially same effect as one illustrated in FIG. 2A may be obtained from the structure of the pixel array 20 of FIG. 4.

Also, the width “w” of each of the metal layers 29 may vary according to an exemplary embodiment. According to an exemplary embodiment, the width “w” of each of the metal layers 29 may be determined based on at least one of the height “h” from the substrate 24 to the microlens 21, the curvature “r” of the microlens 21, and the chief ray angle (CRA) of a main lens (not shown). By implementing the width of each of the metal layers 29, oblique incident light input to an adjacent pixel may be blocked and optical crosstalk between the neighboring pixels may be reduced or alternatively prevented.

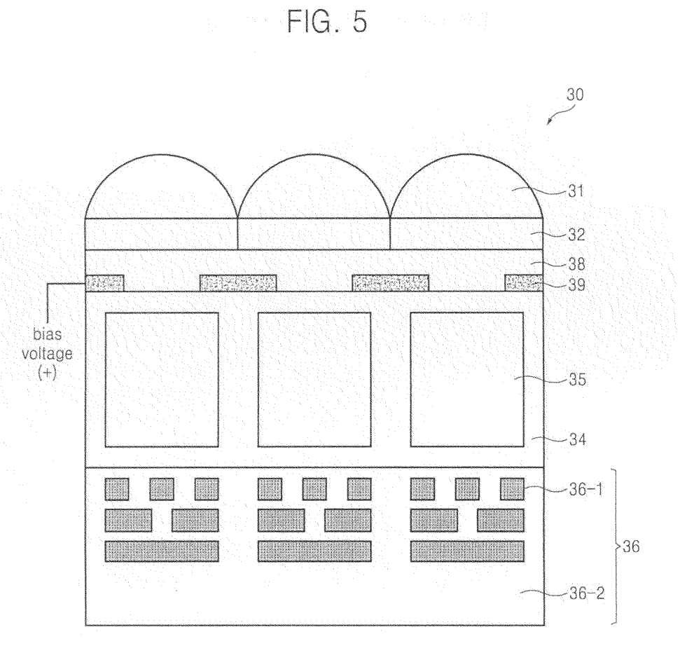

FIG. 5 is a cross sectional view of a pixel array 30 of a back-side illuminated image sensor according to another exemplary embodiment. In FIG. 5, since a microlens 31, a color filter, 32, a photoelectric conversion device 35, a wiring pattern region 36, a metal line 36-1, and an IMD 36-2 are substantially the same as those illustrated in FIGS. 1 and 3, detailed descriptions thereof will be omitted herein.

As illustrated in FIG. 5, a plurality of metal layers 39 are formed on the substrate 34 and the insulation layer 38 may be formed in the upper portion of the metal layers 39. Thus, while the metal layers 29 contact the color filter 22 in FIG. 4, the metal layers 39 may contact the substrate 34 in FIG. 5. According to an exemplary embodiment, the insulation layer 38 may be a planarization (PL) layer. To form the pixel array 30, the metal layers 39 are formed on the substrate 34 and the formed metal layers 39 may be removed as illustrated in FIG. 5. After the metal layers 39 are formed to be separated from each other, the insulation layer 38 may be formed on the upper surface of the substrate 34 and the metal layers 39.

Also, by applying a positive bias voltage to each of the metal layers 39, the potential of the upper surface of the substrate 34 may be decreased. As a result, the generation of electrons in the upper surface of the substrate 34 may be drained. That is, the substantially same effect as one illustrated in FIG. 2B may be obtained from the structure of the pixel array 30 of FIG. 5.

Similarly to FIG. 4, the width of each of the metal layers 39 may be based on at least one of the height from the substrate 34 to the microlens 31, the curvature of the microlens 31, and the CRA of a main lens (not shown). By appropriately implementing the width of each of the metal layers 39, oblique incident light input to an adjacent pixel may be blocked and optical crosstalk between the neighboring pixels may be reduced or alternatively prevented.

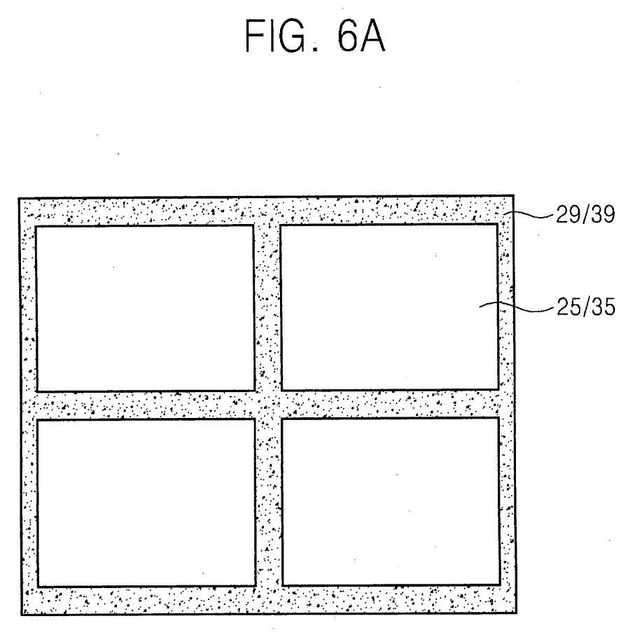

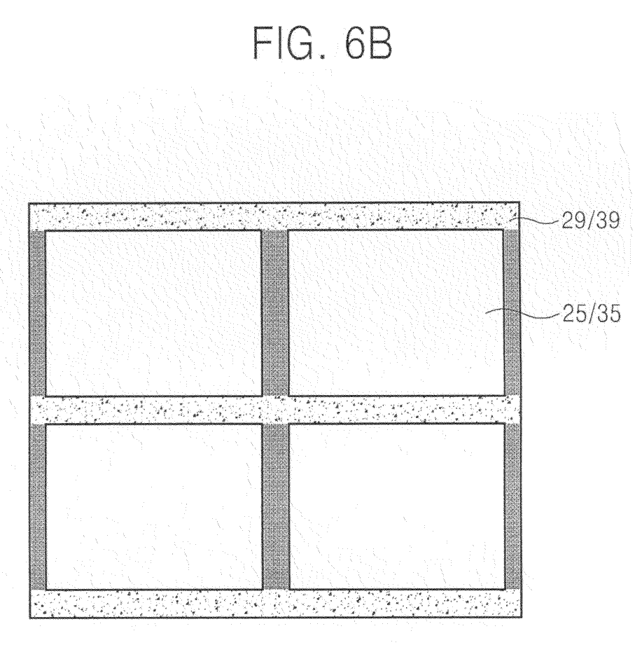

FIGS. 6A and 6B are plain views of the pixel array of a back-side illuminated image sensor according to embodiments. In FIGS. 6A and 6B, for understanding of the structures of the metal layers 29 and 30, only the metal layers 29 and 30 and the photoelectric conversion devices 25 and 35 are illustrated. Referring to FIG. 1-6B, the metal layers 29 and 30 included in the pixel arrays 20 and 30 according to the present exemplary embodiment may be formed in both of first and second directions in which a plurality of photoelectric conversion devices 25 and 35 are arranged, as illustrated in FIG. 6A, or in any one of the directions in which a plurality of photoelectric conversion devices 25 and 35 are arranged, as illustrated in FIG. 6B.

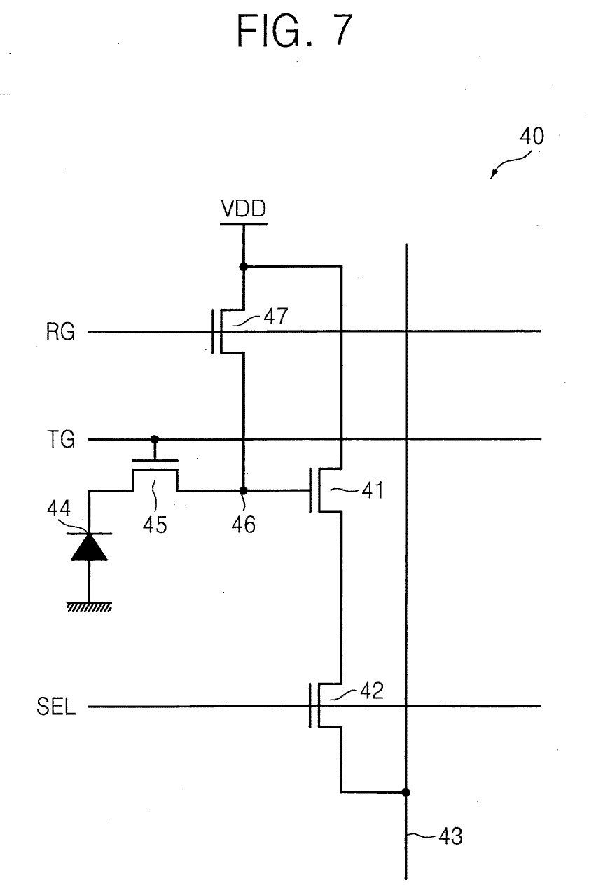

FIG. 7 is a circuit diagram of a unit pixel 40 included in a back-side illuminated image sensor according to an exemplary embodiment. As illustrated in FIG. 7, a pixel may include four transistors. Referring to FIG. 7, the unit pixel 40 may include a photodiode 44, a floating diffusion region 46, and a plurality of transistors (TRs) 41, 42, 45, and 47. The photodiode 44 may generate photons in response to externally incident light. A transfer TR 45, in response to a transmission signal TG, may transmit the photons generated by the photodiode 44 to the floating diffusion region 46.

The reset TR 47, in response to a reset signal RG, may reset the floating diffusion region 46 to a required or alternatively predetermined voltage, for example, VDD. A source of the reset TR 47 may be connected to diffusion region 46 and a drain of the reset TR 47 may be connected to the voltage VDD.

The drive TR 41, in response to a voltage level of the floating diffusion region 46, may output a varying voltage through a vertical signal line 43. A source of the drive TR 41 may be connected to a drain of selection transistor 42, and a drain of the drive TR 41 may be connected to the voltage VDD.

The selection TR 42, in response to a selection signal SEL, may select a unit pixel to output a pixel signal. A source of the selection TR 42 may be connected to a vertical signal 43.

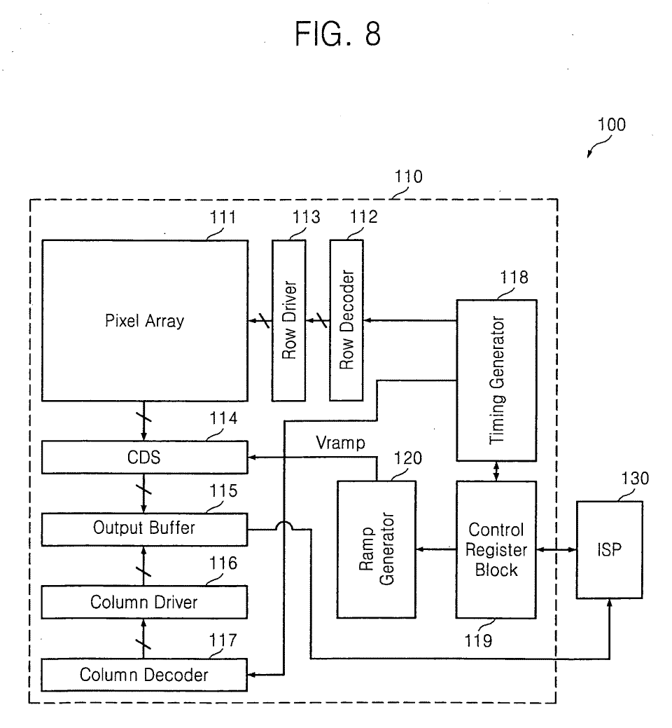

FIG. 8 is a block diagram of an image sensor 100 according to an exemplary embodiment. Referring to FIGS. 1-8, the image sensor 100 according to the an exemplary embodiment may include a photoelectric conversion unit 110 and an image processor 130. Each of the photoelectric conversion unit 110 and the image processor 130 may be implemented by a separate chip or module unit.

The photoelectric conversion unit 110 may generate an image signal to an object based on the incident light. The photoelectric conversion unit 110 may include a pixel array 111, a row decoder 112, a row driver 113, a correlated double sampling (CDS) block 114, an output buffer 115, a column driver 116, a column decoder 117, a timing generator 118, a control register block 119, and a ramp signal generator 120.

The pixel array 111 may include the pixel arrays 10, 20, and 30 illustrated in FIGS. 1, 3, 5, and 6, and a plurality of pixels in a matrix format, each being connected to a plurality of row lines (not shown) and a plurality of column lines (not shown). Each of the pixels may include a red pixel to convert light in a red spectrum range into an electric signal, a green pixel to convert light in a green spectrum range into an electric signal, and a blue pixel to convert light in a blue spectrum range into an electric signal. Also, as illustrated in FIGS. 1, 3, 4, and 5, the color filters 12, 22, and 32 to selectively transmit light in a particular spectrum range may be arranged above the respective pixels.

The row decoder 112 may decode a row control signal, for example, an address signal, generated by the timing generator 118. The row driver 113 may select at least one of the row lines constituting the pixel array 111, in response to a decoded row control signal from row driver 113.

The CDS block 114 may perform CDS on a pixel signal output from a unit pixel connected to any one of the column lines constituting the pixel array 111 to generate a sampling signal (not shown), and compares the sampling signal and a ramp signal Vramp to output a digital signal according to a result of the comparison.

The output buffer 115 may buffer and output signals output from the CDS block 114, in response to a column control signal, for example, an address signal, output from the column driver 116. The column driver 116 may selectively activate at least one of the column lines of the pixel array 111, in response to a decoded control signal, for example, an address signal, output from the column decoder 117. The column decoder 117 may decode a column control signal, for example, an address signal, generated by the timing generator 118.

The timing generator 118 may generate a control signal to control the operation of at least one of the pixel array 111, the row decoder 112, the output buffer 115, the column decoder 117, and the ramp signal generator 120, based on a command output from the control register block 119. The control register block 119 may generate various commands to control elements constituting the photoelectric conversion unit 110. The ramp signal generator 120 may output the ramp signal Vramp to the CDS block 114, in response to a command output from the control register block 119. The image processor 130 may generate an image of the object based on the pixel signals output from the photoelectric conversion unit 110, based on signals generated from the output buffer 115 and the CDS block 114.

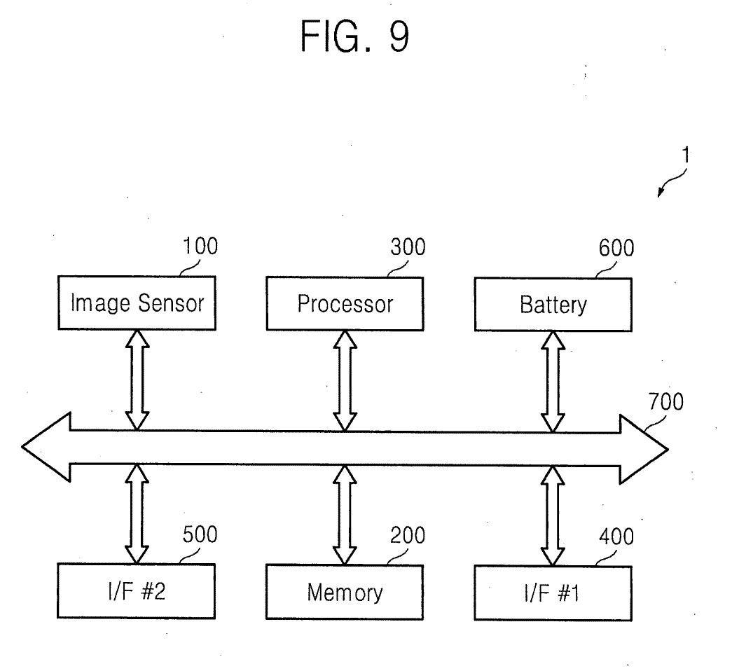

FIG. 9 is a block diagram of a semiconductor system 1 including the image sensor 100 according to an exemplary embodiment. Referring to FIG. 9, the semiconductor system 1 according to the present exemplary embodiment may include the image sensor 100, a memory device 200, and a processor 300 which are connected to a system bus 700. The processor 300 may generate control signals to control the operations of the image sensor 100 and the memory device 200. The image sensor 100 may generate an image of an object. The memory device 200 may store the image generated by the image sensor 100.

According to an exemplary embodiment, when the semiconductor system (or device) 1 of the present exemplary embodiment is implemented as a portable application, the semiconductor system 1 may further include a battery 600 to supply power in addition to the image sensor 100, the memory device 200, and the processor 300.

The portable application may include portable computers, digital cameras, personal digital assistances (PDAs), cellular telephones, MP3 players, portable multimedia players (PMPs), automotive navigation systems, memory cards, or electronic dictionaries.

Also, the semiconductor system 1 of the present exemplary embodiment may further include an interface, for example, an input/output device (I/F #1) 400, to exchange data with external data processing apparatuses. Furthermore, when the semiconductor system 1 of the present exemplary embodiment is a wireless system, the semiconductor system 1 may further include a wireless interface (I/F #2) 500. The wireless system may be a wireless device such as PDAs, portable computers, wireless telephones, pagers, and digital cameras, an RF reader, or an RFID system. Also, the wireless system may be a wireless local area network (WLAN) or a wireless personal area network (WPAN). Furthermore, the wireless system may be a cellular network.

As described above, the image sensor according to the present inventive concept may suppress the generation of dark current in the surface of a silicon substrate and prevent a blooming phenomenon between the photoelectric conversion devices, thereby providing a clear image. Also, the image sensor according to the present inventive concept may prevent optical crosstalk between pixels, thereby providing a clear image.

While embodiments have been particularly shown and described with reference to exemplary embodiments thereof, it will be understood that various changes in form and details may be made therein without departing from the spirit and scope of the following claims.

What is claimed is:

1. A back-side illuminated image sensor comprising:
a substrate including a plurality of photoelectric conversion devices, the photoelectric conversion devices being separated by a semiconductor material; and
a transparent electrode layer formed on the substrate and one of a positive bias voltage and a negative bias voltage is applied.

2. The back-side illuminated sensor of claim 1, wherein the photoelectric conversion devices are n-type and the semiconductor material is a p-type.

3. The back-side illuminated sensor of claim 1, wherein the photoelectric conversion devices are p-type and the semiconductor material is a n-type.

4. The back-side illuminated image sensor of claim 1, further comprising an insulation layer formed under the transparent electrode layer.

5. The back-side illuminated image sensor of claim 4, wherein the transparent electrode layer includes at least one of an oxide and a polymer.

6. The back-side illuminated image sensor of claim 5, wherein the transparent electrode layer is formed in a single pattern on an active pixel sensor (APS) region.

7. The back-side illuminated image sensor of claim 5, wherein the transparent electrode layer includes a plurality of transparent electrodes corresponding to each pixel.

8. A back-side illuminated image sensor comprising:
a substrate including a plurality of photoelectric conversion devices, the photoelectric conversion devices being separated by a semiconductor material;
an insulation layer formed on the substrate; and
a plurality of metal layers formed in at least one of an upper and a lower portion of the insulation layer and being separated from each other.

9. The back-side illuminated sensor of claim 8, wherein the photoelectric conversion devices are n-type and the semiconductor material is a p-type.

10. The back-side illuminated sensor of claim 8, wherein the photoelectric conversion devices are p-type and the semiconductor material is a n-type.

11. The back-side illuminated image sensor of claim 8, wherein, the plurality of metal layers are formed in the upper portion of the insulation layer, are insulated from the substrate, and receive a negative bias voltage is applied during operation.

12. The back-side illuminated image sensor of claim 8, wherein, the plurality of metal layers are formed in the lower portion of the insulation layer, are electrically connected to the substrate, and receive a positive bias voltage during operation.

13. The back-side illuminated image sensor of claim 8, being driven by a first power voltage and a second power voltage higher than the first power voltage,
wherein the plurality of metal layers receive one of a negative bias voltage and a positive bias voltage during operation, and
the negative bias voltage is lower than the first power voltage and the positive bias voltage is higher than the second power voltage.

14. A semiconductor system comprising the back-side illuminated image sensor of claim 8.
